(19) United States
(12) Patent Application Publication
(10) Pub. No.: US 2004/0244191 A1
(43) Pub. Date: Dec. 9, 2004

(54) Method of fabrication of micro-devices

(76) Inventors: Bruce Orr, Alexandria (AU); Brett Sexton, Clayton (AU)

Correspondence Address: CONNOLLY BOVE LODGE & HUTZ LLP, SUITE 800, 1990 M STREET NW, WASHINGTON, DC, 20036-3425, US

(21) Appl. No.: 10/492,153

(22) PCT Filed: Oct. 24, 2002
(86) PCT No.: PCT/AU02/01438

(30) Foreign Application Priority Data
Oct. 25, 2001 (AU) PR 8467

(51) Int. Cl. H05K 3/10

(52) U.S. Cl. 29/842; 29/846

(57) ABSTRACT

A method of fabricating electromechanical devices such as micro relays on printed circuit boards. The method includes the deposition of an element of the component onto an electrically conducting sacrificial layer, which is subsequently removed to form a PCB component that is suspended above the PCB substrate. In one embodiment, the vias in a multilayer PCB are used as the anchor posts for the suspended component.

### FIELD OF THE INVENTION

This invention relates to miniaturized elements and their manufacture using existing and adapted technologies. In particular, the invention relates to miniaturized elements manufactured on a substrate using known and adapted PCB manufacturing technologies.

### BACKGROUND OF THE INVENTION

Printed circuit boards are known as a means of providing electrical interconnection between electronic components. Basically a PCB consists of an insulating substrate, commonly made of an epoxy resin fibreglass, coated with a conductive layer, usually copper, affixed to one or both sides. A circuit design engineer will determine the layout of the components and the required conductive interconnections, and the pattern of interconnections will be etched on the PCB, usually using a photomask to protect the selected connection paths from the etchant. The result is an insulating carrier board with a pattern of copper tracks defining the interconnections between the electronic components to be affixed to the board.

Multi-layer PCBs are also known, in which additional copper tracks are incorporated between two or more insulating layers. There may be many such layers. The tracks on different layers can be connected by the use of through-holes, called vias, which may be plated-through to provide electrical connection between the layers. PCB manufacturing facilities commonly use photo lithography, laminating and electroplating which are relatively inexpensive methods.

Micro-machine technology such as micro-electromechanical systems (MEMS) are a more recent development and are directed to producing very small scale devices compared to PCB dimensions, often having moving components. MEMS is based on silicon fabrication, and uses similar processes to those used to manufacture integrated circuits. One of the features of MEMS type manufacturing processes is that they are very specialized, requiring high precision techniques and specialized equipment. For example vapour deposition is a commonly used step in MEMS fabrication which is a relatively expensive step. Some inexpensive fabrication steps like laminating are inappropriate for MEMS fabrication because of the relatively brittle nature of the commonly used silicon wafer.

The article “Low cost technology for multilayer electroplated parts using laminated dry film resist” H. Lorenz, et al describes the formation of epitaxial gear moulds using multi layer photoresist in the field of MEMS technology.

U.S. Pat. No. 5,430,421 describes a technique for the relief of stress in the formation of a double armature reed relay for MEMS applications using electroplating methods. The technique described uses vapour deposition of a sacrificial conducting layer onto which the reed relay component is electrodeposited.

U.S. Pat. No. 6,040,748 describes a method for alleviating stress bending in a MEMS relay by increasing the thickness of the armature and reducing the cross section of an intermediate portion of the armature to maintain flexibility. The stress is greatest in the initially deposited layer, so increasing thickness reduces the unwanted curling effect due to the stress.

None of these prior publications disclose or suggest the use or adaptation of PCB fabrication processes to manufacture miniaturized devices. It is an object of this invention to provide a method of fabricating electro mechanical devices on PCB substrates using PCB equipment and adapted PCB techniques.

### SUMMARY OF THE INVENTION

This invention is based on the insight that the technology used for printed circuit board manufacture can be adapted to the manufacture of on-board items other than conductive tracks. In particular, these techniques can be used to produce elements which are partly or wholly detached from the substrate. In some applications, the elements are designed to have one or more degrees of movement. In other applications, the elements may be intended to be mechanically fixed, but may be designed to be at least partially removed from contact with other material. An example of the latter is an air-core inductor. This device may have its ends electrically connected into a circuit, but the coil is suspended in a cavity.

This invention therefore provides a method of fabricating a miniaturized element on a PCB substrate using existing and adapted PCB fabrication processes to fabricate elements on a substrate, wherein one or more elements are partially or completely detached from the substrate while optionally retaining a working interrelationship with other elements on the substrate.

The elements may be formed by an additive process such as electroplating or chemical plating, or by a subtractive process, such as etching.

In one application, the element or an element preform is applied to a sacrificial release layer located between the element fabrication layer and another layer or the substrate, the release layer being subsequently removed when the element is sufficiently formed and/or attached. In conventional PCB methods sacrificial layers are not located beneath a formed element or between the element and the PCB substrate.

In the case where the release layer is conductive, the element may be wholly or partially formed onto the release layer by electroplating through a mask which permits some or all of the features of the element to be plated onto the release layer. In the case where the release layer is not conductive, a conductive seed layer is first deposited on the release layer, the mask applied and the element or parts of the element are electroplated onto the seed layer.

In an alternative embodiment, an element fabrication layer is formed on or glued to the release layer, masked, and the full or partial elements etched out of the element fabrication layer.

In a further embodiment, further elements or parts of elements are formed in association with or in contact with the previously formed elements or parts of elements.

In another embodiment of the invention, the release layer is processed to include the profile of a desired shape of an element or part of an element before the element is formed on the release layer.

In a still further embodiment; an element fabrication layer is preformed with the profile of an element or part of an element before the element fabrication layer is attached to the release layer.

In one embodiment where the element is to be partially detached, the element may be designed to move relatively to the substrate. Driving means may be provided to move the element. The driving means may be, for example, electromagnetic, electrostatic, thermal (bimorph, memory), electromechanical (piezo).

Preferably, the detachment is performed by the use of a release layer between the part of the element to be detached and the substrate.

The release layer is a sacrificial layer and may be made of, for example, a photoresist layer, a metal layer, or a laminated layer composed of two or more layers of sacrificial material.

Optionally the release layer will be coated on one or both sides with an adhesive.

In one embodiment, a partially cured glass/epoxy composite layer called prepreg is used as the adhesive layer to attach a release layer to a substrate. This process requires the application of elevated and pressures for an extended period of time.

In another embodiment, the release layer is a dry film photoresist. Normally, the photoresist film is coated on one side with an adhesive which may have a peel-off protective layer which is removed immediately before use to expose the adhesive. We have found that the photoresist material such as RISTON (a registered trade mark of E I Du Pont De Nemours and Company) or similar photoresists, when heated to above a predetermined temperature, forms a suitable adhesive for attachment to some release layers or element fabrication layers. An advantage of this process is that the attachment requires lower pressure to obtain adhesion than some other processes. Preferably the process can be carried out using heated rollers at a temperature in the region of 150° C. at a controlled roller.

In another alternative, the release layer may include a metal sheet. This may be affixed to the substrate using an adhesive or the dry photoresist

A sacrificial layer may be applied to the substrate and the element fabrication layer applied to the sacrificial layer. Preferably, the sacrificial layer is formed of a material which is either soluble or preferentially etched by a selected etchant in preference to the element fabrication layer. The element fabrication layer may use a direct element deposition process in which the elements are directly formed on the sacrificial layer (masking of the pattern), or the element fabrication layer may itself be applied as a complete layer, which is etched to leave the desired elements.

One or more of the element fabrication layers, or the underlying sacrificial layer on which an element fabrication layer is to be formed, may be preformed or partly preformed to facilitate the fabrication of the elements. For example the outline of the element may be pressed or stamped into the element fabrication layer to give the element a preferred shape before the supporting matrix of the element fabrication layer is etched. Alternatively, the elements may wholly or partially stamped out of the element fabrication layer and held together by a web or matrix before applying the element fabrication layer to the substrate. Alternatively, portions of the “waste” areas of the element fabrication layer may be cut away before attaching the layer to reduce the subsequent processing time. Similar techniques may be applied to the sacrificial layer to add a profile to the sacrificial layer where the element fabrication layer is to be formed on the sacrificial layer, eg, by electro or chemical deposition.

In another embodiment, the substrate is a multi-layer PCB.

The invention also contemplates an embodiment in which vias are provided in the substrate. In some applications, the vias are filled or lined with electrical and/or magnetic path material.

The techniques outlined above may be used to form miniature components that are at a larger scale than MEMS products but are able to be made using less expensive techniques.

The products formed will usually include a portion achored to the substrate and apportion that is free of the substrate such as:

Reed relays consisting of a reed cantilevered out from a post formed on a via of the PCB substrate

Accelerometers or motion sensors incorporating a mass mounted on a spring attached to the PCB substrate

Reflective mirrors or pixel elements free to move relative to the anchor point on the PCB substrate.

### BRIEF DESCRIPTION OF THE DRAWINGS

FIG. 1 shows the initial stages of a process according to an embodiment of the invention.

FIG. 2 shows a first alternative arrangement for connecting an element to the substrate.

FIG. 3 illustrates the main steps of of a process implementing an embodiment of the invention.

FIG. 4 shows the process of forming elements attached to plated-through vias.

FIG. 5 shows a section through a plated-through via.

FIG. 6 illustrates the main steps of a process of this invention for fabricating a micro relay component;

### DETAILED DESCRIPTION OF THE EMBODIMENTS

The invention will be described with reference to the drawings.

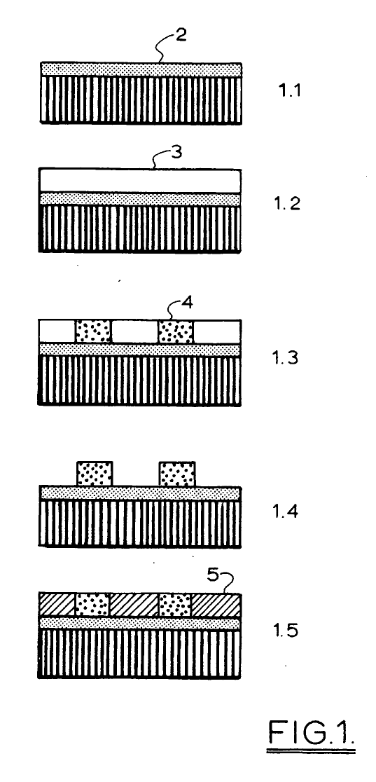

FIG. 1 shows a typical process for producing elements according to a first embodiment of the invention.

In step 1.1, a substrate 1 is coated with a sacrificial layer 2. The substrate may be made of a substance suitable for use in a PCB fabrication process. The sacrificial layer is selected for its amenability to being dissolved or etched in preference to the element fabrication layer and the substrate. The sacrificial layer may be, for example a soluble non-metallic layer, a plastic layer, a metal layer, or a laminate of metal and non-metal. In one embodiment the sacrificial layer is made of aluminium or zinc sheet which is glued to the substrate by a suitable adhesive.

In a particularly advantageous application, the aluminium sacrificial layer may be glued to the substrate by using a dry protoresist film as the adhesive layer. The normal adhesive face of the film may be used to attach the film to one surface, while the previously unknown “hot melt” adhesive quality of the film may be used to attach to the other surface. This process can be carried out with the use of a hot roller mechanism, pressing the three components (substrate, film, sacrificial layer sheet together) with a heated rolled. The combination of heat and pressure ensuring good bonding.

In step 1.2, a layer of photoresist 3 is applied to the sacrificial layer 2. This layer may be applied by known techniques. Preferably, a dry photoresist film is applied to the sacrificial layer by removing the adhesive protection and applying the film in the known manner.

In step 1.3, the photoresist is masked (not shown) with the desired pattern, exposed to UV radiation in selected areas, 4, to selectively harden the exposed photoresist.

In step 1.4, the undeveloped resist is developed using known techniques, leaving the hardened areas 4 on the sacrificial layer 3.

In step 1.5, the material 5 to be used for the elements (left sloping diagonal shading) is applied, eg, by electroplating, the photoresist preventing the deposition in areas where the developed resist is present. There may be particular reasons for plating more than one type of material as the element fabrication layer. For example, a metal element may be provided with a thin layer of gold to improve characteristics such as electrical connectivity. The improvement of corrosion resistance is another example of an application in which more than one metal is used in the element. Another application is where it is desired to take advantage of different properties of different metals, such as magnetic susceptibility and electrical or thermal conductivity, or different rates of thermal expansion of different materials.

It should be noted that, where the sacrificial layer is non-conducting, a step of coating it with seed layer of conductive material would be used when the sacrificial layer is applied. This then enables a subsequent step of applying another layer such as the element fabrication layer to the sacrificial layer by electroplating.

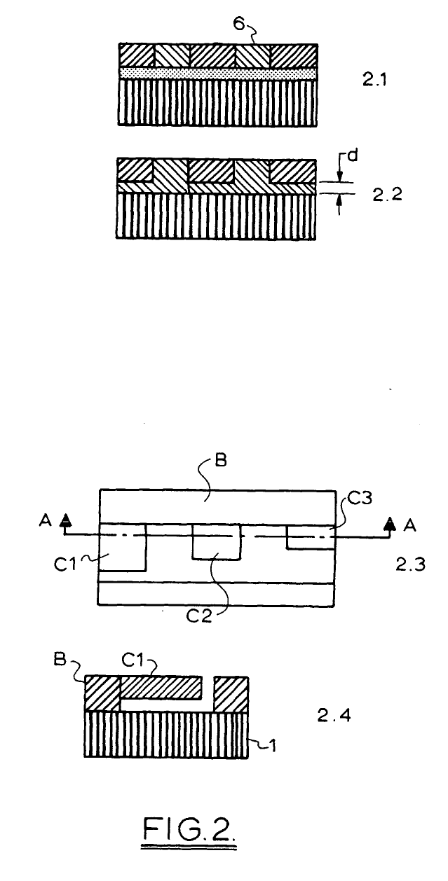

In FIG. 2, a support member B is shown by way of illustrative example as an attachment between the elements and the substrate. Our preferred means of attaching the elements to the substrate is by the use of “posts” formed using extended plated through vias. This is described in more detail below with reference to FIGS. 5 & 6.

Returning to the illustrative example in FIG. 2.1, the developed photoresist is removed, eg, in a caustic solution. The right sloping diagonal shaded area is the rear wall of the cavity left by the developed photoresist when it is removed in the caustic bath. See discussion below of the plan view in FIG. 2.3. At this stage, the elements C1, C2, C3, are partially released, but are still attached to the sacrificial layer 2 and the transverse member B.

In step 1.7, the sacrificial layer 2 is removed by dissolving in a solution which dissolves the sacrificial layer material 2 in preference to the element material 5. This then frees the elements C1, C2, C3, so that they are only attached to the transverse member B.

FIG. 2.3 and FIG. 2.4 show plan and side views of the end result of the process shown in FIGS. 1.1 to FIG. 2.2. As is best seen in the side elevation, the element C1 is an overhanging element spaced a distance “d” above the substrate 1. The plan view shows similar, progressively shorter, overhanging elements C2 & C3. The elements C1, C2, and C3 are affixed to the transverse element B, which is attached to the substrate 1.

The formation of element B has not been discussed in detail, but it can readily be fabricated, for example, in a first step before step 1.1 to remove the part of the sacrificial layer under the B footprint, and then laying down a first stage of the same thickness as the sacrificial layer. The remainder of B is built up at the same time as the elements C1, C2, and C3 are deposited.

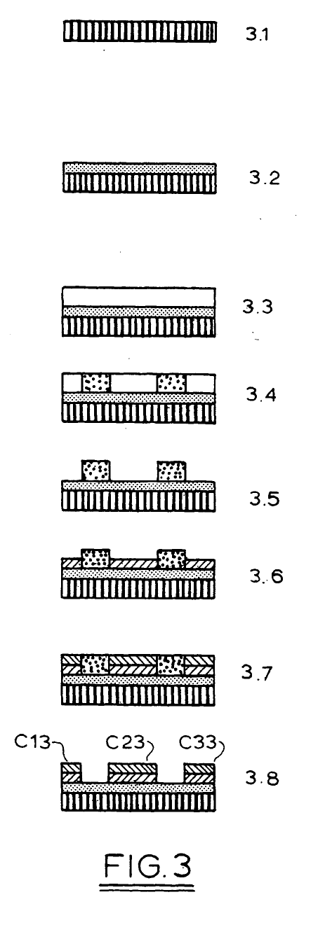

As discussed more fully below, in an alternative to the provision of the support B, in some cases it may be preferable to provide plated-through holes (vias) which can be extended to a desired height above the substrate to act as supports for the elements. More complex shapes and additional layers may be constructed using this process. We will now consider the preparation of a pre-plated aluminium sheet with reference to FIGS. 3 & 4.

FIG. 3 illustrates the process steps for the preparation of a combined sacrificial layer and element fabrication layer in an alternative embodiment of the invention. Some of the preparatory and intermediate steps are not shown on FIG. 3.

With reference to FIG. 3, the process includes the following stages:

Stage 3.1: Clean the aluminium used for the sacrificial or release layer.

Stage 3.2 (optionally) The surface of the aluminium is micro-etched promote adhesion during the plating process. At this stage, a cleaning step, not shown, may be used to remove unwanted material such as silicon produced by the earlier steps.

Stage 3.2: Zinc plating is performed using the zincate electroless method. We have found that interposing a zinc layer between the aluminium and the nickel produces better results for some applications. This step is not required if the release layer is made of zinc.

Stage 3.4: Rinse and dry process (not shown in FIG. 3) is performed.

Stage 3.5: A photoresist layer is applied to the zinc, preferably using the dry film photoresist. This step is illustrated at stage 3.3 of FIG. 3.

Stage 3.6: The photoresist is masked and exposed to UV light to selectively harden it. This stage is illustrated at 3.4 in FIG. 3.

Stage 3.7: Remove the unexposed resist using a developer. This corresponds to FIG. 3.5.

Stage 4.8: A gold layer is deposited by electroplating. This is usually a thin layer. The photoresist prevents deposition on the zinc except at the locations determined by the mask. This step is illustrated at 3.6 in FIG. 3.

An intermediate rinse step at this point is not shown.

Stage 3.9: A layer of nickel is then deposited on the gold layer by electroplating. This corresponds to stage 3.7 in FIG. 3.

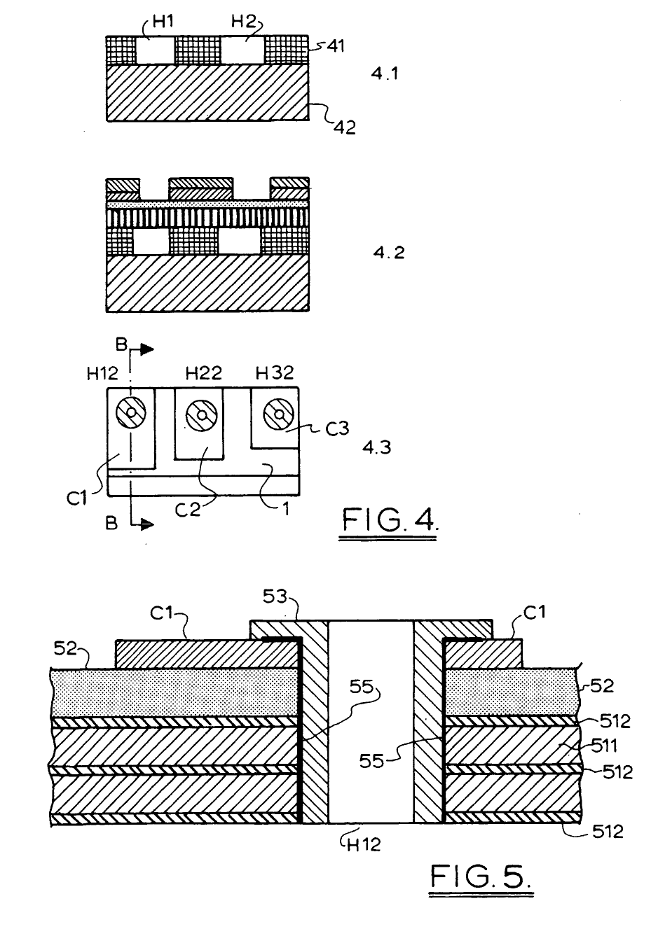

Stage 3.10: A caustic strip is then used to remove the developed photoresist. This is illustrated at 3.8 in FIG. 4. The resulting nickel cantilever has a gold plating on the underside from Stage 3.9. This may be useful, for example if it is desired to make electrical contact to this surface.

This process results in the formation of the elements C13, C23, C33, being formed on the sacrificial release layer consisting of a zinc and aluminium laminate. This combination can now be applied to a substrate, eg, by using the dry film photoresist adhesive process described above. The advantage of using this adhesive process becomes clear when it is realized that the lower pressure and temperature conditions of this adhesion process reduce the probability of damage to the structure formed on the sacrificial release layer.

In an alternative embodiment, a further process may be added, eg, by adding a further layer to part of one or more of the elements. An additional photo-mask is applied over the composite, preferably before the caustic strip process shown at step 3.10. The photoresist is processed, and additional material is deposited in the required locations.

Turning now to the application of the pre-plated sacrificial layer to the substrate and the formation of extended support posts formed on plated through vias, this process is illustrated in FIGS. 4 & 5

As shown in FIG. 4.1, a prepreg (epoxy/glass) layer 41 is applied to a substrate, PCB 42. The prepreg 41 optionally has holes predrilled.

FIG. 4.2 shows the pre-plated aluminium sacrificial layer from FIG. 3.8, with the elements pre-formed on its surface, attached to the prepreg 41. This attachment may be performed by a hot press operation in which the assembly is heated for a period of the order of 1 hour under pressure. This operation uses the prepreg as an adhesive layer to attach the pre-plated aluminium layer.

FIG. 4.3 shows a plan view of the result of a number of subsequent operations to be described below.

When the assembly has cooled, effectively gluing the prepreg and the pre-plated aluminium together, holes H12, H22, and H32 are drilled through the aluminium and the PCB.

The following process is a preferred method of plating the holes.

A stainless steel mask with openings corresponding to the locations of the holes is applied over the assembly, and a copper seed layer is vacuum deposited into the holes from the steel mask side.

The steel mask is removed, and a photoresist is then applied to the top of the assembly in the usual manner, openings being left corresponding to the location of the holes following the masking, exposure, development, and removal of unexposed resist steps.

Similarly the bottom surface (the PCB lower surface) is coated with photoresist, also leaving the holes open.

Nickel or other selected metal is then plated through the hole using an electroplating process onto the seed copper lining. The material selected for plating the holes may be chosen for its electrical conductivity and/or magnetic susceptibility. Nickel exhibits both properties.

The resist is then stripped, leaving the assembly shown in FIG. 4.3.

FIG. 5 shows the detail of a plated-through via, as an expanded partial view of a section through the line B′B″ in FIG. 4.3. The substrate is, in this example, a multi layer PCB having alternate conducting and/or magnetic layers 512 interspersed between insulating layers 511 the sacrificial release layer 52 is applied on top of the substrate, and a first deposition pattern is applied to form the elements C1 etc. Preferably the deposition is nickel. The hole H12 is then drilled through the element C1, the release layer 52 (which may optionally be predrilled), and the layers of the substrate.

In order to make it possible to electroplate the inside of the hole H12, a conductive seed layer 55, for example of copper, is applied to the inside of the hole. In this case, an overlap of the seed layer with the top of the element C1 improve adhesion between the plating in the via and the element. The seed layer may be formed by a vapour deposition, all areas where the seed layer is not required being masked. Alternatively, chemical deposition may be used. After the seed layer is formed, electrical contact is made with the seed layer, and the assembly is immersed in a plating bath. In order to improve the penetration of the plating material into the vias, relative motion may be applied between the plating solution and the assembly, axially in relation to the vias. This may be done by moving the board or by imparting flow to the plating solution.

When the elements are attached to their corresponding attachment points, the sacrificial release layer is dissolved. In one embodiment, the sacrificial release layer is aluminium. Instead of aluminium, other materials may be used for the release layer. Zinc or copper are other suitable metals which may be used.

In some applications, it may be desirable to enclose the elements in a cavity. This may be achieved by placing a spacer around the elements and bonding it to the substrate, and then bonding a lid onto the spacer. The spacer may enclose single elements, groups of elements in a single cavity, or all elements in a single cavity. Alternatively the lid may be another substrate or PCB.

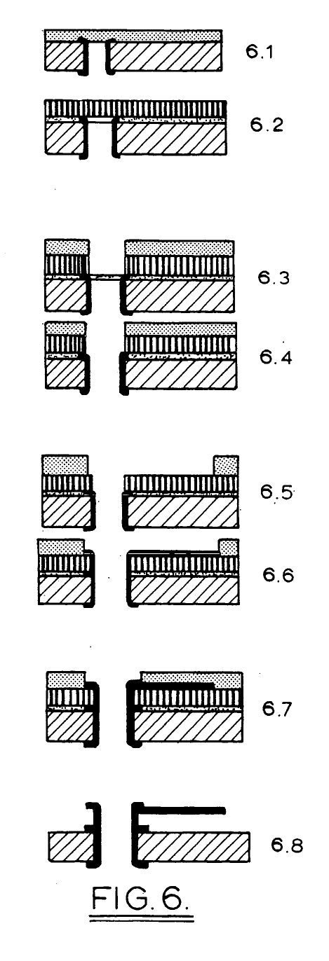

FIG. 6 show the steps for preparing a micro relay component in which suspended cantilevers are attached to a multilayer circuit board. A relay of this type is disclosed in European patent specification 1241697.

Stage 6.1 Dry film photoresist is laminated to the upper surface of a clean, prefabricated multi layer printed circuit board. This board contains prefabricated vias or through holes which are electroplated with gold as the final step. (see FIG. 6.1) A protective film is applied to the rear of the PCB to protect circuit tracks during the subsequent process steps.

Stage 6.2 Copper foil (typically 35 micrometers thick) is laminated to the top surface of the photoresist layer using a hot roll laminator at 105° C. Alignment holes are predrilled through the foil using pre existing alignment vias on the multi layer PCB as a guide. (see FIG. 6.2).

Stage 6.3 A further dry film resist is applied to the upper surface of the copper foilusing a hot roll laminator. A photomask is applied and is photo exposed so that circular apertures are formed using the drilled alignment holes as guides. These apertures coincide with the locations of the support posts in the final structure and also coinside with the plated through vias on the underlying PCB.

Stage 6.4 The exposed copper is chemically etched with an etchant such as ammonium persulphate to form circular apertures in the sacrificial copper layer. (see FIG. 6.3).

Stage 6.5 The thin film resist blocking the holes is removed with sodium carbonate solution. At this stage, depending on the design of the multilayer PCB the copper sacrifial layer is electrically connected to the PCB plated through vias, by contact pressure during lamination. (see FIG. 6.4).

Stage 6.6 The upper photoresist layer is removed by caustic stripping.

Stage 6.7 A new layer of dry film resist is laminated to the upper surface. This surface is photopatterned with a new mask having the preferred cantilevered shape defined on it and then the pattern is developed. The ends of the cantilever pattern are collocated with the holes in the underlying copper layer. (see FIG. 6.5).

Stage 6.8 The exposed cantilever patterns are electroplated with gold/nickel/gold to the desired thickness. (see FIG. 6.6).

Stage 6.9 The upper resist layer is caustic stripped and a new dry film resist is re applied by lamination. A new layer is photopatterned to provide circular apertures coinciding with the locations of the support post holes.

Stage 6.10 A thicker nickel layer is electroplated to provide a strong support post. (see FIG. 6.7).

Stage 6.11 The sacrificial copper layer is removed by preferential chemical etching using an etchant such as ammonium persulphate.

Stage 6;12 The adhesive photoresist layer is removed by caustic stippping to reveal the final product with suspended gold plated cantilevers or actuators attached to the multilayer PCB by nickel posts. (see FIG. 6.8).

These steps may be carried out to form an array of cantilevered reeds for use as an array of microrelays.

Those skilled in the art will realise that a number of PCB techniques have been adapted for novel uses in the above described process.

Stages 6.1 and 6.2 use the photo resist layer as an adhesive to bond the sacrificial copper layer to the PCB substrate

Electrical contact with the sacrificial layer is achieved in stage 6.5

The vias are electroplated to provide support posts for the cantilevered reeds in stage 6.10

In stages 6.11 and 6.12 gentler removal (as by soaking rather than spraying) of the sacrificial layer and the photoresist layer are required to avoid damaging the cantilevered structure.

It will be understood that the invention disclosed and defined herein extends to all alternative combinations of two or more of the individual features mentioned or evident from the text or drawings. All of these different combinations constitute various alternative aspects of the invention.

The foregoing describes embodiments of the present invention and modifications, obvious to those skilled in the art can be made thereto, without departing from the scope of the present invention.

1. A process for manufacturing a miniaturized element on a substrate using existing and adapted PCB fabrication processes in which an element is partially or completely detached from the substrate, the element first being formed as an attachment to the substrate through a release layer, the release layer being removed during or after the process of forming the element.

2. A process as in claim 1 wherein the release layer is electrically conducting and the element is formed by forming a mask layer on top of the release layer and electroplating through the mask layer onto the conducting release layer.

3. A process as in claim 1 wherein the release layer is non-conducting and the element is formed by depositing a conducting seed layer on top of the release layer, forming a mask layer on top of the seed layer and electroplating through the mask layer onto the conducting seed layer.

4. A process as in claim 1 wherein the element is formed by applying a layer of element material to the release layer, applying a mask layer to the element material and then etching away the element material in the areas not covered by the mask layer.

5. A process as claimed in claim 1 wherein the element layer is pre-assembled with the release layer before attachment to the substrate.

6. A process as in claim 2 wherein further elements are formed over the whole or part of the element using processes as per claim 2 but with the substrate layer replaced with the underlying element layer.

7. A process as in claim 6 wherein the release is omitted between one or more element layers so that element layers are in contact.

8. A process as in claim 7 wherein the additional element layer is formed by electroplating and is plated onto (bonded with) the the underlying element layer.

9. A process as in claim 1, wherein the element is fixed to the substrate at one or more points using one or more holes etched, drilled or formed
through the release layer, said holes being through plated, through coated or filled to provide attachment.

10. A process as in claim 9 wherein the coated/filled holes also provide electrical conduction pathways.

11. A process as in claim 9 wherein the coated/filled holes also provide magnetic conduction pathways.

12. A process as in claim 1, wherein a plurality of elements is formed concurrently in each layer using masks for each layer defining said plurality of elements.

13. A process as in claim 1 wherein a second substrate is bonded using a spacer layer to the first substrate so that the elements are encapsulated between the substrates.

14. A process as in claim 1 wherein a protective cap is attached to one or both sides of the composite structure.

15. A process as in claim 1 wherein the substrate(s) contains magnetically conducting pathways.

16. A process as in claim 1 wherein the substrate(s) contains electrically conducting pathways.

17. Process as in claim 1 wherein the substrate(s) contains electrodes.

18. A process as in claim 1 wherein the substrate(s) contains coils.

19. A process as in claim 1 wherein the substrate(s) is a multi-layer printed circuit board.

20. A process as in claim 1 wherein the release layer a photoresist film.

21. A process as claimed claim 1 wherein the release layer is a metal foil or sheet.

22. A process as claimed in claim 1 wherein the metal foil or sheet is attached with an adhesive layer.

23. A process as claimed in claim 1 wherein the adhesive layer is prepreg.

24. A process as claimed claim 1 wherein the adhesive layer is thermally bonded dry photoresist film

25. A method of fabricating a miniaturized element on a substrate using existing and adapted PCB fabrication processes to fabricate elements on a substrate, wherein one or more elements are partially or completely detached from the substrate while retaining a working interrelationship with other elements on the substrate.

26. A method as claimed in claim 1 wherein the release layer is processed to include the profile of a desired shape of an element or part of an element before the element is formed on the release layer.

27. A method as claimed in claim 25 wherein an element fabrication layer is profiled with the profile of an element or part of an element before the element fabrication layer is formed on or attached to the release layer.

28. A process as in claim 1, wherein the element is attached at one or more points to one more support structures, said one or more support structures being deposited on the substrate and attached to the substrate.

29. A process of forming an element on a PCB substrate in which
a) a sacrificial electrically conductive layer is adhered to the substrate
b) a metal layer is electroplated onto said sacrificial layer to form said element
c) the sacrificial layer is removed by etching or dissolution to release the element.

30. A process as claimed in claim 29 in which the substrate incorporates electrically conducting vias and the electroplating of the metal layer extends to and/or into the vias.

31. A process of forming a micro reed onto a PCB board using the process defined in claim 30 in which the electroplated vias form the support posts and the reeds are formed by electroplating onto the electrically conductive sacrificial layer and freed by etching or dissolution of the electrically conductive sacrificial layer.
